(19) United States
(12) Patent Application Publication
(10) Pub. No.: US 2024/0248045 A1
(43) Pub. Date: Jul. 25, 2024

(54) MASK AND PROCEDURE FOR PROCESS PERFORMANCE DETECTION

(71) Applicant: Onto Innovation Inc., Wilmington, MA (US)

(72) Inventors: Kevin Eduard HEIDRICH, Golden, CO (US); Nicholas James KELLER, Pasadena, CA (US)

(21) Appl. No.: 18/101,534

(22) Filed: Jan. 25, 2023

(51) Int. Cl. G01N 21/95

(52) U.S. Cl. CPC G01N 21/9501

(57) ABSTRACT

A metrology target is configured for measurement or inspection of the performance of processing of a sample, such as a semiconductor sample. The metrology target includes a plurality of target structures, each with a different pattern density and having a plurality of regions with different lengths. The metrology target captures a range of device characteristics that may be measured or inspected as a proxy for devices on the sample with corresponding device characteristics. The metrology target may be used to determine areas (device characteristics) where artifacts remain after material removal, such as etching or chemical-mechanical planarization (CMP) or for other process marginalities, such as over polish, or fill overburden. A processing score may be determined for the metrology target, each target structure, each region in each target structure, or any combination thereof, e.g., based on a comparison to a reference region or to an expected model or simulation result.

### FIELD OF THE DISCLOSURE

Implementations of the subject matter described herein are related generally to optical metrology and inspection, and more particularly to mask design and metrology and inspection method for process performance detection.

### BACKGROUND

Semiconductor and other similar industries often use optical metrology equipment to provide non-contact evaluation of samples during processing. With optical metrology, a sample under test is illuminated with light, e.g., at a single wavelength or multiple wavelengths. After interacting with the sample, the resulting light is detected and analyzed to determine one or more characteristics of the sample.

Manufacturing processing used in semiconductor and similar industries relies on sequential processes that build up layers to produce electronic circuits or the like. The manufacturing tolerances in advanced nodes are very small and the device layout and design have a direct impact on the manufacturing quality of the final device. For example, during processing material may be selectively removed or removed in bulk using, for example, etch processing, chemical-mechanical planarization (CMP) or a chemical-mechanical polishing process to planarize a top surface of a substrate between levels. The process used to remove material, however, may not be uniform and may result in either material removal that is too fast or too slow in various areas. It is desirable to measure or inspect devices to enable localization, detection, and measurement of process marginalities.

### SUMMARY

A metrology target is configured for measurement or inspection of the performance of processing of a sample, such as a semiconductor sample. The metrology target is configured to capture a range of device characteristics. For example, the metrology target includes a plurality of target structures, each with a different pattern density (e.g. line/space density) and each having a plurality of regions with different lengths. The metrology target may be measured or inspected as a proxy for devices on the sample with corresponding device characteristics. The metrology target, for example, may be measured or inspected to determine device characteristics, which correspond to areas on nearby devices, where artifacts, such as residue, erosion, dishing, etc., may remain after a material removal process, such as etching or chemical-mechanical planarization (CMP), or for other process marginalities, such as over polish, or fill overburden. A processing score may be determined for the metrology target, each target structure, each region in each target structure, or any combination thereof, e.g., based on a comparison to a reference region or to an expected model or simulation result. The processing score(s) may be reported to a user or may be reported to another system, such as external process tools, in a feed forward or feedback process in order to adjust a process parameter associated with a fabrication process step of the samples based on the measurement results.

In one implementation, a metrology target for measurement or inspection for processing of a sample includes a plurality of target structures. Each target structure has a different pattern density, and each target structure has a plurality of regions having different length scales. Each region in each target structure includes a location for the measurement or inspection for processing of the sample.

In one implementation, a method of measurement or inspection for processing of a sample includes adjusting a relative position of a metrology or inspection device with respect to a metrology target on the sample after processing of the sample. The metrology target includes a plurality of target structures. Each target structure has a different pattern density, and each target structure has a plurality of regions having different length scales. Metrology or inspection data is acquired from each of the plurality of regions for each target structure. A processing score is determined for at least one of the metrology target or each target structure or each region of each target structure.

In one implementation, a metrology target for measurement or inspection for processing of a sample includes at least three target structures. Each target structure has a plurality of regions with lines and spaces. Each region in a target structure has different lengths along an axis that is perpendicular to the lines. Further, each of the target structures has a different line/space density. The regions in the target structures represent the device characteristics that correspond to areas on nearby devices on the sample.

### BRIEF DESCRIPTION OF THE DRAWINGS

FIGS. 1A and 1B illustrate processing steps that may be used during manufacturing a semiconductor device or the like, which results in undesired residue after a material removal step.

FIG. 2 illustrates a wafer with a number of dies with residue remaining in various areas.

FIGS. 3A and 3B are block diagrams illustrating environment for processing a sample substrate with a metrology tool evaluating the processing performance.

FIG. 4 illustrates a schematic view of an example of a metrology device that may be used for metrology or inspection of a target on a sample.

FIG. 5A illustrates an example of a target for measurement or inspection of process performance for a sample.

FIG. 5B illustrates the target from FIG. 5A with optical metrology measurement or inspection locations and an example of residue remaining after a material removal process.

FIG. 6A illustrates another example of a target for measurement or inspection of process performance for a sample.

FIG. 6B illustrates the target from FIG. 6A with voltage contrast measurement or inspection and an example of residue remaining after a material removal process.

FIG. 7 illustrates a method of measurement or inspection for processing of a sample using a metrology target as discussed herein.

### DETAILED DESCRIPTION

During fabrication of semiconductor and similar devices it is very often necessary to monitor the fabrication process by non-destructively measuring the devices. Optical metrology and inspection may be employed for non-contact evaluation of samples during processing.

Manufacturing of semiconductor devices and other similar types of devices relies on sequential processing to build up layers to form the devices. Each layer, for example, may be produced by deposition of materials on a substrate, e.g., using well known deposition techniques such as physical vapor deposition (PVD), chemical vapor deposition (CVD), electrochemical deposition (ECD), molecular beam epitaxy (MBE), atomic layer deposition (ALD) and other methods. After depositing the material, the material may be selectively removed or removed in bulk. For example, material may be removed using an etch process, such as wet etching in a chemical bath and/or dry etching using an ion bombardment such as reactive ion etch. Etching, for example, may be used to selectively remove exposed regions of a substrate after a photolithographic mask has been applied. Alternatively, material may be removed in bulk using, for example, etch processing, chemical-mechanical planarization (CMP) or a chemical-mechanical polishing process to planarize a top surface of the substrate between layers. The process of removing material, however, may leave undesired artifacts, e.g., due to process variations, such as residue due to under polish or erosion or dishing due to over polish.

As a specific example, semiconductor manufacturing utilizes CMP to polish away (clear) overburden on top of previously filled structures. The polish process has a characteristic clearing behavior based on the choice of consumables in the polisher, the polisher settings, the incoming device materials and thicknesses, and the layout (devices features) of the specific device. Device density variations will result in areas in a production device that have marginal process windows, either polishing too fast or polishing (clearing) too slowly, which are referred to as “hot spots.”

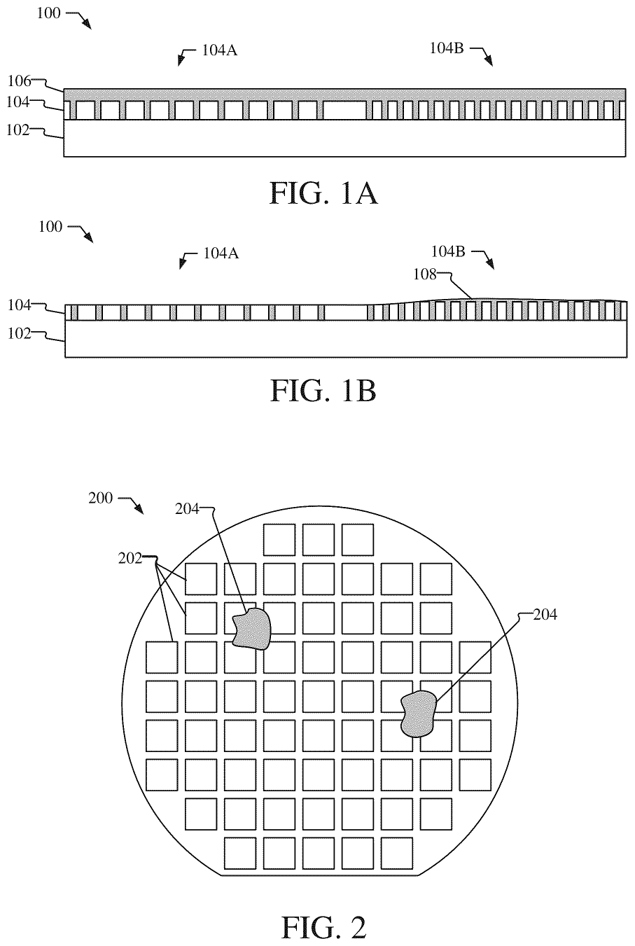

FIGS. 1A and 1B, by way of example, illustrate processing steps that may be used during manufacturing a semiconductor device or the like, which results in undesired artifacts after a material removal step. FIG. 1A illustrates a sample 100 with a relatively planar surface layer 102, which may be, e.g., a silicon substrate, with a patterned layer 104 deposited thereon. The patterned layer 104, for example, may be a dielectric layer, e.g., an oxide layer, which is patterned and etched using a photolithographic process to generate spaces in the material of patterned layer 104. As illustrated by regions 104a and 104b, the patterned layer 104 has a variation in density. Another layer 106, e.g., a metal layer such as copper, is blanket deposited over the patterned layer 104. FIG. 1B illustrates the sample 100 after removal of material from layer 106 (shown in FIG. 1A), e.g., using a CMP step, to planarize the surface. As illustrated, residue 108 of the material from layer 106 may remain in some areas of the sample 100 after the material removal process while other areas may be cleared. Additionally or alternatively, other artifacts, such as erosion or dishing, may remain after the material removal process. The presence of artifacts, such as residue 108 in some areas but not others, is due to the various processing conditions, including the process parameters (e.g., polisher consumables and settings), as well as the device materials, thicknesses and layout. For example, as illustrated in FIG. 1B, the material removal in region 104B with greater pattern density is slower than in region 104A, resulting in residue 108 in region 104B.

FIG. 2 illustrates a wafer 200 with a number of dies 202. Each die on wafer 200 may have the same pattern. Nevertheless, due to process conditions including wafer characteristics, such as bowing, dishing, etc., residue 204 may remain in various areas of the wafer 200, while being cleared from other areas of the wafer 200.

It is desirable to measure or inspect samples for hot-spot type of behavior. As discussed herein, a target, e.g., on a mask and transferred to the device, is produced that captures the range of processing conditions to localize hot-spot type of behavior and build up a proxy device that is representative of the behavior of production die. The use of a target that serves as a proxy device that is representative of the behavior of the production die, i.e., with respect to hot-spot type of behaviors, is advantageous as measurement/inspection of the target may be used to determine whether artifacts, such as residue, is likely present on a device after processing without requiring inspection of the entire device. Similarly, with the presence of such a target in various areas of a wafer, the measurement/inspection of the targets across the wafer may be used to determine whether artifacts, such as residue, is likely in various areas of the wafer after processing without requiring inspection of the entire wafer.

The target for measurement or inspection for artifacts, such as residue, erosion, dishing, etc., on a sample includes a structure with a gradient of densities at different length scales that will polish preferentially faster or slower than the rest of the device. The target can be designed and optimized for metrology and inspection with various methods. In one implementation, the layout of a passive target may be designed for inspection or metrology with an optical metrology tool, such as a spectroscopic ellipsometer, spectroscopic reflectometer, ultra-fast laser pump/probe acoustic microscopy, or other similar optical metrology instrumentation. In another implementation, the layout of the target may be electrically optimized to be either floating or grounded for interrogation with a voltage contrast scanning electron microscope (VC SEM) or similar metrology instrumentation. The measurement system used with the target may use a probe beam that is substantially smaller than the target in order to interrogate different areas of the target. The target may further include a reference cell for an uncleared (full pattern) area.

The target may be analyzed with multiple measurements and differential or comparative analysis to any one region may be performed to determine spectroscopic differences, or the target may be measured and compared to an expected model or simulation result. The target may be assigned a clearing or process window score or merit function to represent the clearing fraction. In the case of a voltage contrast measurement, the layout will result in a response of clear (bright and not shorted to ground), or dark (residue bridge to ground). A similar merit function score can be provided for voltage contrast measurements.

In addition to residue detection, a similar target design may be used for other process marginalities, such as over polish, fill overburden (e.g., utilizing ultrafast laser acoustic microscopy).

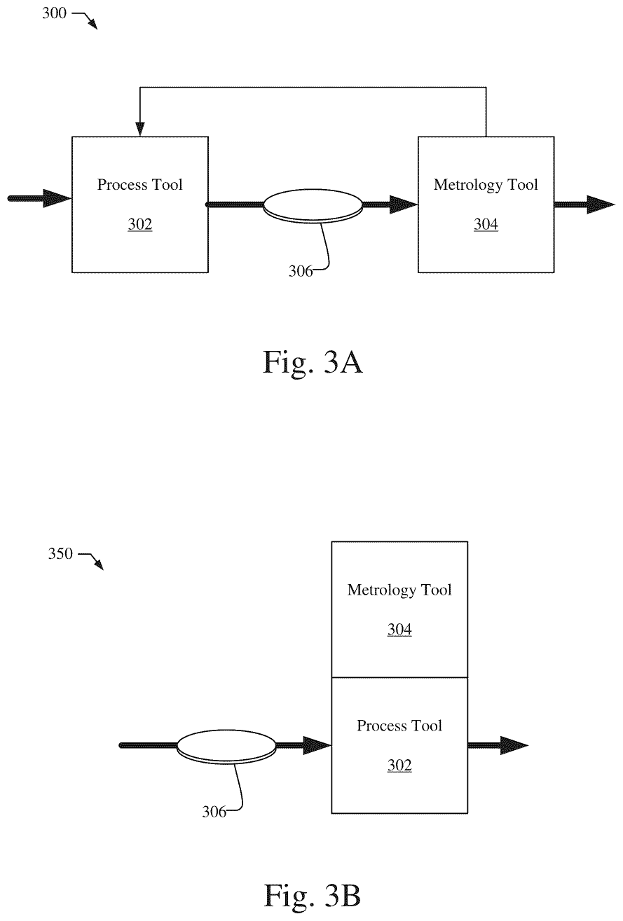

FIG. 3A is a block diagram illustrating an environment 300 for processing a sample substrate 306. The processing environment 300 includes a process tool 302 and a metrology tool 304 for evaluating the processing performance. The substrate 306 may include a silicon wafer, a photolithographic mask, a gallium arsenide wafer, a germanium wafer, etc. The process tool 302 is configured to perform a process on the substrate 306. For clarity, only one process tool 302 is illustrated in FIG. 3A; however, a person of ordinary skill in the art would understand that multiple process tools 302 may each perform one or more processes on the layer of the substrate 306. A typical substrate may include one or more semiconductor devices arranged on the substrate as an array of one or more dies, while a typical semiconductor device may include multiple layers (e.g., source layer, drain layer, capacitor layer, resistor layer, gate layer, contact pad layer, conductor layer, etc.). Typical processes, include deposition of material onto the substrate 306, removal of material from the substrate 306, patterning of the substrate 306, and selective modification of the chemical composition of material in the substrate 306 to modify electrical properties of patterned regions.

In various implementations, the process tool 302 may be configured to selectively remove material from one or more layers of the substrate 306, or remove the material from the substrate 306 in bulk. For example, material may be removed using an etch process, such as wet etching in a chemical bath and/or dry etching using an ion bombardment such as reactive ion etch. In some implementations, the process tool 302 may use etch processing to selectively remove exposed regions of a substrate after a photolithographic mask has been applied. Alternatively, the process tool 302 may be configured to remove material in bulk using, for example, etch processing, chemical-mechanical planarization (CMP) or a chemical mechanical polishing process to planarize a top surface of the substrate 306 between levels.

Patterning techniques are typically used for selectively depositing or removing material and/or controlling the shape of the deposited material. For example, in a conventional technique known as lithography, the substrate 306 is coated with a photoresist. Selected portions of the photoresist may be exposed using a lithographic mask. The exposed regions of photoresist on the substrate 306 are then washed away by a developer solution. Alternatively, the unexposed regions of the photoresist may be washed away by the developer solution. The process tool 302 may then deposit material onto, remove material from, or modify material in the regions of the substrate 306 where the photoresist has been washed away.

Deposition, removal, and/or modification may be performed in multiple steps on the substrate 306. Some steps may leave a layer of material on the substrate 306 which has optical properties, such as an index of refraction, coefficient of transmission, coefficient of extinction, etc. The process tool 302 may produce a uniform layer of material across the substrate 306 or may produce a layer in selective locations on the substrate 306 using lithographic techniques.

The metrology tool 304 is configured to measure a target on the substrate 306 that has been deposited, removed, and/or modified by the process tool 302 and serves as a proxy device that is representative of material removal process on the substrate 306, as described herein. The metrology tool 304, for example, may be a spectroscopic ellipsometer, spectroscopic reflectometer, ultra-fast laser pump/probe acoustic microscopy, VC SEM, or other similar metrology related instruments capable of measurement/inspection of a target on the substrate 306 as discussed herein. The metrology tool 304 is further configured to provide information about the target on the substrate 306 to the process tool 302. The process tool 302 may use the information received from the metrology tool 304 to modify a process being applied to a subsequent substrate 306.

FIG. 3B is a block diagram illustrating an alternative implementation of an environment 350 for processing the substrate 306. FIG. 3B differs from FIG. 3A in that the metrology tool 304 is configured to measure the substrate 306 while the substrate 306 is in the process tool 302 and a process is being performed on the substrate 306. In some implementations, the process tool 302 is configured to receive measurements from the metrology tool 304 during the process and modify the process according to the information received from the metrology tool. For example, the process tool 302 may receive real time measurements of artifacts, such as residue, erosion, dishing, etc., on the target on the substrate 306 from the metrology tool 304 during the material removal process, and may continue or stop the material removal process in response to the real time measurements to achieve a desired thickness and clearing of the material.

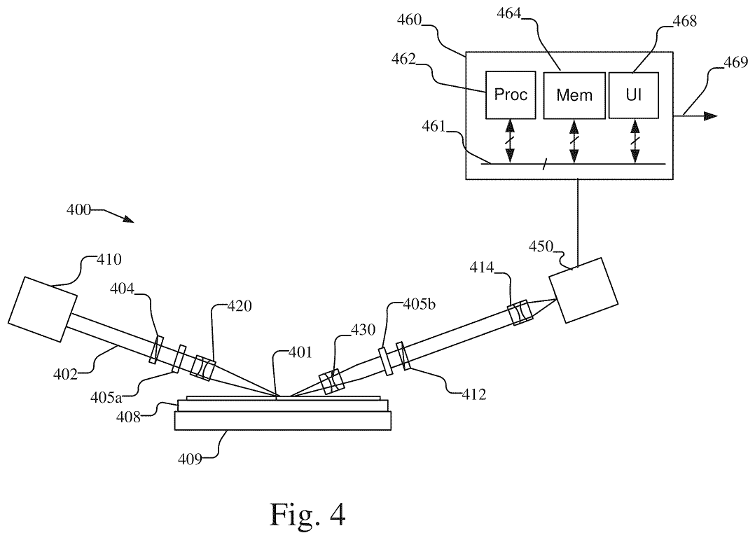

FIG. 4, by way of example, illustrates a schematic view of an optical metrology device 400 that may be used for metrology or inspection of a target on a sample as described herein. The optical metrology device 400 may be one example of the metrology tool 304 in FIGS. 3A and 3B. The optical metrology device 400 may be configured to perform, e.g., spectroscopic reflectometry, spectroscopic ellipsometry (including Mueller matrix ellipsometry), spectroscopic scatterometry, overlay scatterometry, interferometry, or FTIR measurements, of a target on the sample 401. It should be understood that optical metrology device 400 is illustrated as one example of a metrology device, and that if desired other metrology devices may be used, including normal incidence devices, non-polarizing devices, etc.

Optical metrology device 400 includes a light source 410 that produces light 402. The light 402, for example, UV-visible light with wavelengths, e.g., between 400 nm and 1000 nm. The light 402 produced by light source 410 may include a range of wavelengths, i.e., continuous range or a plurality of discrete wavelengths, or may be a single wavelength. The optical metrology device 400 includes focusing optics 420 and 430 that focus and receive the light and direct the light to be obliquely incident on a top surface of the sample 401. The optics 420, 430 may be refractive, reflective, or a combination thereof and may be an objective lens.

The reflected light may be focused by lens 414 and received by a detector 450. The detector 450, may be a conventional charge coupled device (CCD), photodiode array, CMOS, or similar type of detector. The detector 450 may be, e.g., a spectrometer if broadband light is used, and detector 450 may generate a spectral signal as a function of wavelength. A spectrometer may be used to disperse the full spectrum of the received light into spectral components across an array of detector pixels. One or more polarizing elements may be in the beam path of the optical metrology device 400. For example, optical metrology device 400 may include one or both (or none) of one or more polarizing elements 404 in the beam path before the sample 401, and a polarizing element (analyzer) 412 in the beam path after the sample 401, and may include one or more additional elements, such as a compensator or photoelastic modulator, which may be before, after, or both before and after the sample 401, as illustrated by 405a and 405b. With the use of a spectroscopic ellipsometer using dual rotating compensators, between polarizing elements 404 and 412 and the sample, a full Mueller matrix may be measured if desired.

Optical metrology device 400 further includes one or more computing systems 460 that is configured to perform measurements or inspection of the target on the sample 401 as described herein. The one or more computing systems 460 is coupled to the detector 450 to receive the data acquired by the detector 450 during measurement/inspection of the structure of the target on the sample 401. The one or more computing systems 460, for example, may be a workstation, a personal computer, central processing unit or other adequate computer system, or multiple systems.

It should be understood that the one or more computing systems 460 may be a single computer system or multiple separate or linked computer systems, which may be interchangeably referred to herein as computing system 460, at least one computing system 460, one or more computing systems 460. The computing system 460 may be included in or is connected to or otherwise associated with optical metrology device 400. Different subsystems of the optical metrology device 400 may each include a computing system that is configured for carrying out steps associated with the associated subsystem. The computing system 460, for example, may control the positioning of the sample 401, e.g., by controlling movement of a stage 409 that is coupled to the chuck. The stage 409, for example, may be capable of horizontal motion in either Cartesian (i.e., X and Y) coordinates, or Polar (i.e., R and θ) coordinates or some combination of the two. The stage may also be capable of vertical motion along the Z coordinate. The computing system 460 may further control the operation of the chuck 408 to hold or release the sample 401. The computing system 460 may further control or monitor the rotation of one or more polarizing elements, such as polarizing elements 404 and 412, and other components such as compensators 405a and 405b, etc.

The computing system 460 may be communicatively coupled to the detector 450 in any manner known in the art. For example, the one or more computing systems 460 may be coupled to a separate computing systems that is associated with the detector 450. The computing system 460 may be configured to receive and/or acquire data or information from one or more subsystems of the optical metrology device 400, e.g., the detector 450, as well as controllers polarizing elements 404, 412, and compensator(s) 405a, 405b, etc., by a transmission medium that may include wireline and/or wireless portions. The transmission medium, thus, may serve as a data link between the computing system 460 and other subsystems of the optical metrology device 400.

The computing system 460, which includes at least one processor 462 with memory 464, as well as a user interface (UI) 468, which are communicatively coupled via a bus 461. The memory 464 or other non-transitory computer-usable storage medium, includes computer-readable program code embodied thereof and may be used by the computing system 460 for causing the at least one computing system 460 to control the optical metrology device 400 and to perform the functions including the measurement/inspection of the target as described herein. For example, as illustrated, memory 464 may include instructions that configure the at least one processor 462 to measure and analyze multiple positions within a target. The at least one processor 462 may be configured to analyze the target with multiple measurements and perform a differential or comparative analysis to any one region to determine spectroscopic differences, or to compare the measured data to an expected model or simulation result. The at least one processor 462 may assign a clearing or process window score or merit function to the target to represent the clearing fraction. The data structures and software code for automatically implementing one or more acts described in this detailed description can be implemented by one of ordinary skill in the art in light of the present disclosure and stored, e.g., on a computer-usable storage medium, e.g., memory 464, which may be any device or medium that can store code and/or data for use by a computer system, such as the computing system 460. The computer-usable storage medium may be, but is not limited to, include read-only memory, a random access memory, magnetic and optical storage devices such as disk drives, magnetic tape, etc. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described.

The results from the analysis of the data may be reported, e.g., stored in memory 464 associated with the target on the sample 401 and/or indicated to a user via UI 468, an alarm or other output device. Moreover, the results from the analysis may be reported and fed back or forward to the process equipment (as illustrated in FIGS. 3A and 3B) to adjust the appropriate fabrication steps to compensate for any detected variances in the fabrication process. The computing system 460, for example, may include a communication port 469 that may be any type of communication connection, such as to the internet or any other computer network. The communication port 469 may be used to receive instructions that are used to program the computing system 460 to perform any one or more of the functions described herein and/or to export signals, e.g., with measurement results and/or instructions, to another system, such as external process tools, in a feed forward or feedback process in order to adjust a process parameter associated with a fabrication process step of the samples based on the measurement results.

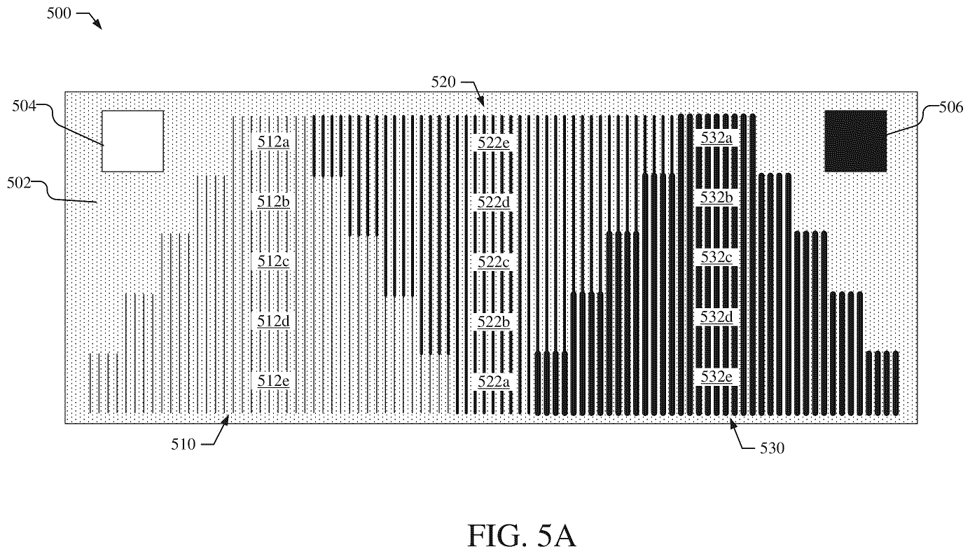

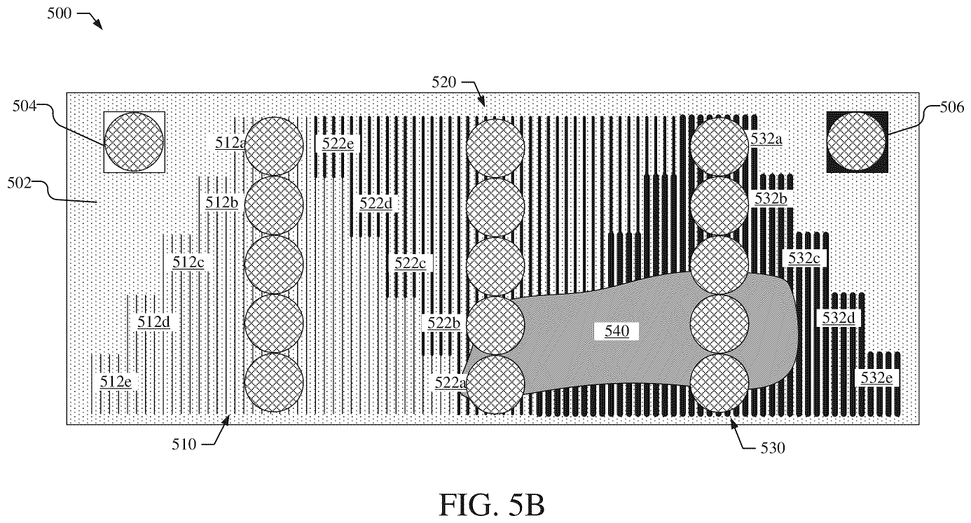

FIG. 5A illustrates a target 500 for measurement or inspection of process performance for a sample. The target 500 captures a range of processing conditions and may be used to localize areas where material removal may occur too slowly leaving residue, e.g., “hot spots.” In addition to residue detection, target 500 (or a similarly designed target) may be used for other process marginalities, such as over polish, fill overburden, erosion, dishing, etc. The structure of the target 500 may be produced on a mask to be transferred to a sample during processing of the sample. The target 500, when present on the sample, provides a representation of the behavior of the material removal process on the sample over various device characteristics, e.g., device layout including density variations. Accordingly, the target 500 may serve as a proxy device that may be measured/inspected to determine if artifacts, such as residue, is present in areas of proximate devices with corresponding device characteristics, thereby eliminating (or reducing) the need to measure/inspect the devices themselves.

Target 500 includes one or more structures with a gradient of pattern densities at different length scales, which will effect material removal faster or slower than other areas of the target 500, and in some implementations, proximate devices on the sample. FIG. 5A illustrates three structures 510, 520, and 530, each with a different pattern density (by way of example, 20%, 50% and 80%) and multiple length scales. If desired, additional structures or fewer structures (e.g., at least two) may be included in the target 500 to respectively increase or reduce the number of pattern densities, and additional length scales or fewer length scales (e.g., at least two) may be included in each structure. While the structures 510, 520, and 530 in target 500 are illustrated as lines and spaces, it should be understood that any type of structure may be used including posts or columns.

Structure 510, for example, is a low density line structure, e.g., with a density of 20% line/space with the minimum line width, but other densities may be used, e.g., greater or less densities. The structure 510 may be a line structure and may be end cap shorted or serpentine. As illustrated, the structure 510 has five regions with different length scales, illustrated as 512a, 512b, 512c, 512d, and 512e, sometimes collectively referred to as regions 512. The length scale, in this example, refers to the length of the regions 512, where the length is along an axis that is perpendicular to the lines in the regions 512. The structure 510 may not include a via to ground.

Structure 520 is similar to structure 510, but is a mid-density line structure, e.g., with a density of 50% line/space, but other densities may be used, e.g., greater or less densities. The structure 520 may be a line structure and may be end cap shorted or serpentine. As illustrated, the structure 520 has five regions with different length scales, illustrated as 522a, 522b, 522c, 522d, and 522e, sometimes collectively referred to as regions 522, e.g., where the length is along an axis that is perpendicular to the lines. The structure 520 may not include a via to ground. As illustrated, structure 520 may be inverted with respect to structures 510 and 530 to minimize the area occupied by the target 500.

Structure 530 is similar to structure 510, but is a high density line structure, e.g., with a density of 80% line/space with the maximum line width, but other densities may be used, e.g., greater or less densities. The structure 530 may be a line structure and may be end cap shorted or serpentine. As illustrated, the structure 530 has five regions with different length scales, illustrated as 532a, 532b, 532c, 532d, and 532e, sometimes collectively referred to as regions 532, e.g., where the length is along an axis that is perpendicular to the lines. The structure 530 may not include a via to ground.

The target 500 may further include a field 502 of dummy fill that is introduced per design rules that surrounds the structures 510, 520, and 530. The dummy fill, for example, may be used to equalize the spatial density of the layout, improving uniformity of the CMP process. The target 500 may further include one or more regions with no pattern, which may be used as reference cells for an uncleared or full pattern area. For example, the target 500 may include a region 504 without a pattern with no fill, and the target 500 may include a region 506 without a pattern with 100% fill. Regions 504 and 506 may sometimes be referred to as reference cells 504 and 506.

The target 500 may be designed and optimized for a particular metrology and inspection process and tool to be used, such as a spectroscopic ellipsometer, spectroscopic reflectometer, ultra-fast laser pump/probe acoustic microscopy, or other similar optical metrology instrumentation. Moreover, the target 500 may be designed based on the characteristics of proximate devices, so that the densities and lengths scales of the various structures in target 500 serve as a representation or proxy for the various regions in proximate devices.

FIG. 5B illustrates the target 500 transferred to a sample after a material removal process, e.g., CMP, in which residue 540 remains over portions of structures 520 and 530. As illustrated by hatched circles in FIG. 5B, the target 500 may be optically measured/inspected at a plurality of locations by a metrology instrument, e.g., metrology tool 304 or optical metrology device 400. The metrology instrument used to measure/inspect the target 500 uses a probe spot that is substantially smaller than the target so that multiple locations of the target 500 may be measured/inspected, as illustrated by each hatched circle. For example, each length scale of each structure 510, 520, and 530, is separately measured/inspected. The one or more reference cells 504 and 506 may also be measured/inspected.

The target 500, for example, may be analyzed with multiple measurements and differential or comparative analysis to any one region, e.g., to a reference cell 504 and/or 506 may be performed to determine spectroscopic differences, or the target 500 may be measured and compared to an expected model or simulation result. Based on the results of the measurements/inspection, the target 500 and/or target structures within the target 500 or each region within each target structure in the target 500 may be assigned a clearing or process window score or merit function to represent the clearing fraction. For example, a merit function of the target 500 that is below a threshold, may indicate that all regions of the target 500 have been cleared and, accordingly, each area in nearby devices that corresponds to a region of the target 500 are likely cleared, and thus further material removal (CMP) may be stopped and inspection of nearby devices may be unnecessary. Alternatively, the merit function of the target 500 may be above a threshold indicating that one or more regions of the target 500 have not been adequately cleared and, accordingly, further material removal (CMP) is necessary and/or additional measurement/inspection of nearby devices for artifacts, such as residue, may be necessary. In some implementations, a merit function of specific regions of the target 500 may indicate that they have not been adequately cleared and, accordingly, the areas of nearby devices that correspond to these specific regions may require additional measurement/inspection. For example, as illustrated in FIG. 5B, measurement/inspection of regions 522a and 522b of structure 520 and regions 532c, 532d, and 532e of structure 530 may result in a merit function indicating that residue 540 is present in these regions, and accordingly, further material removal (CMP) is necessary and/or additional measurement/inspection for artifacts, such as residue, in areas of nearby devices that correspond to these regions may be necessary.

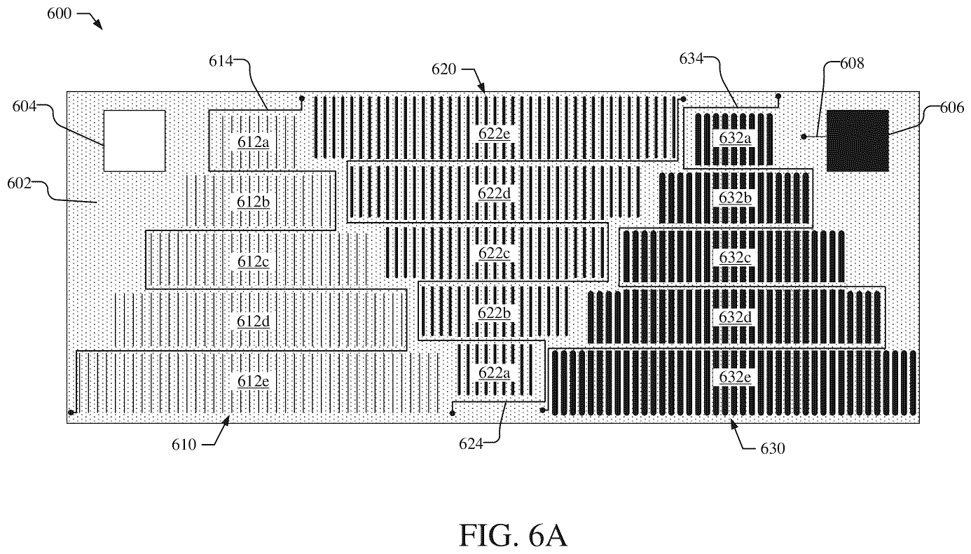

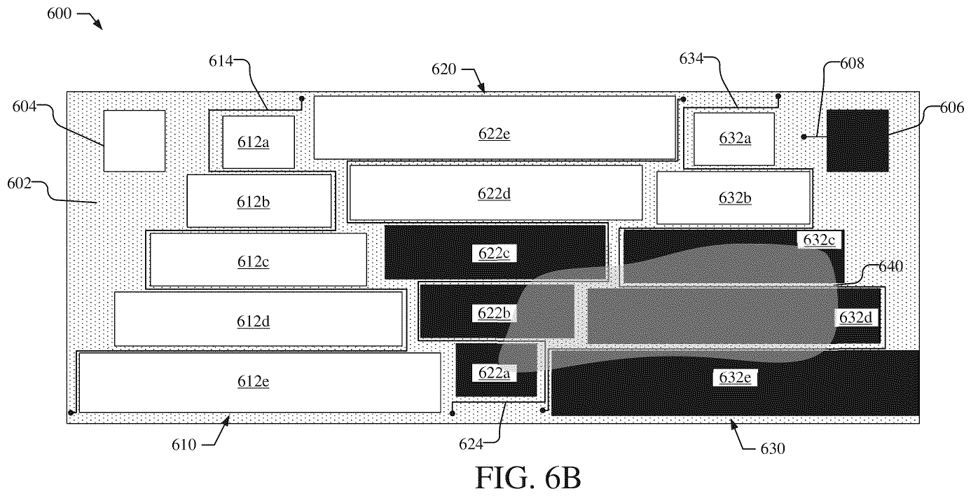

FIG. 6A illustrates target 600 for measurement or inspection of artifacts, such as residue, on a sample. The target 600 is similar to target 500, discussed in FIGS. 5A and 5B, but target 600 is designed as a voltage contrast target, which may be measured using a VC SEM or other similar instrument. Similar to target 500, the target 600 captures a range of processing conditions and may be used to localize areas where material removal may occur too slowly leaving residue, e.g., “hot spots.” In addition to residue detection, target 600 (or a similarly designed target) may be used for other process marginalities, such as over polish, fill overburden, erosion, dishing, etc. The structure of the target 600 may be produced on a mask to be transferred to a sample during processing of the sample. The target 600, when present on the sample, provides a representation of the behavior of the material removal process on the sample over various device characteristics, e.g., device layout including density variations. Accordingly, the target 600 may serve as a proxy device that may be measured/inspected to determine if artifacts, such as residue, is present in areas of proximate devices with corresponding device characteristics, thereby eliminating (or reducing) the need to measure/inspect the devices themselves.

Target 600 is illustrated with three structures 610, 620, and 630, each with a different pattern density (by way of example, 20%, 50% and 80%) and multiple length scales. If desired, additional structures or fewer structures (e.g., at least two) may be included in the target 600 to respectively increase or reduce the number of pattern densities, and additional length scales or fewer length scales (e.g., at least two) may be included in each structure. While the structures 610, 620, and 630 in target 600 are illustrated as lines and spaces, it should be understood that any type of structure may be used including posts or columns.

Structure 610, for example, is a low density line structure, e.g., with a density of 20% line/space with the minimum line width, but other densities may be used, e.g., greater or less densities. The structure 610 may be a line structure and may be end cap shorted or serpentine. As illustrated, the structure 610 has five regions with different length scales, illustrated as 612a, 612b, 612c, 612d, and 612e, sometimes collectively referred to as regions 612, where the length is along an axis that is perpendicular to the lines in the regions 12. As illustrated, the regions 612 are separated and a continuous line 614 with a via to ground extends along the length of each region 612 within the separations between regions 612, while the lines within the regions 612 do not include a via to ground.

Structure 620 is similar to structure 610, but is a mid-density line structure, e.g., with a density of 60% line/space, but other densities may be used, e.g., greater or less densities. The structure 620 may be a line structure and may be end cap shorted or serpentine. As illustrated, the structure 620 has five regions with different length scales, illustrated as 622a, 622b, 622c, 622d, and 622e, sometimes collectively referred to as regions 622, e.g., where the length is along an axis that is perpendicular to the lines. As illustrated, the regions 622 are separated and a continuous line 624 with a via to ground extends along the length of each region 622 within the separations between regions 622, while the lines within the regions 622 do not include a via to ground. As illustrated, structure 620 may be inverted with respect to structures 610 and 630 to minimize the area occupied by the target 600.

Structure 630 is similar to structure 610, but is a high density line structure, e.g., with a density of 80% line/space with the maximum line width, but other densities may be used, e.g., greater or less densities. The structure 630 may be a line structure and may be end cap shorted or serpentine. As illustrated, the structure 630 has five regions with different length scales, illustrated as 632a, 632b, 632c, 632d, and 632e, sometimes collectively referred to as regions 632, e.g., where the length is along an axis that is perpendicular to the lines. As illustrated, the regions 632 are separated and a continuous line 634 with a via to ground extends along the length of each region 632 within the separations between regions 632, while the lines within the regions 632 do not include a via to ground.

The target 600 may further include a field 602 of dummy fill that is introduced per design rules that surrounds the structures 610, 620, and 630. The dummy fill, for example, may be used to equalize the spatial density of the layout, improving uniformity of the CMP process. The target 600 may further include one or more regions with no pattern, which may be used as reference cells for an uncleared or full pattern area. For example, the target 600 may include a region 604 without a pattern with no fill, and the target 600 may include a region 606 without a pattern with 100% fill. As illustrated, region 606 may include a line 608 with via to ground.

The target 600 may be designed and optimized for a particular metrology and inspection process and tool to be used, such as a VC SEM or other similar metrology instrumentation. Moreover, the target 600 may be designed based on the characteristics of proximate devices, so that the densities and lengths scales of the various structures in target 600 serve as a representation or proxy for the various regions in proximate devices.

FIG. 6B illustrates the target 600 transferred to a sample after a material removal process, e.g., CMP, in which a metal residue 640 (shown as transparent) remains over portions of structures 620 and 630. In FIG. 6B, the lines are not individually shown because, for example, the lines are much smaller than the image scale (e.g., the lines may be in the nanometer scale, while visible features in FIG. 6B are in 10s of micrometer scale. As illustrated, in the case of a voltage contrast measurement, the target 600 will produce a response of clear (bright and not shorted to ground) or dark (residue bridge to ground). Thus, as illustrated in FIG. 6B, regions 622a, 622b, and 622c of structure 620 and regions 632c, 632d, and 632e of structure 630 appear dark due to the presence of the metal residue bridging these regions to ground. The line structures in each of the regions 612, 622, and 632, for example, may be serpentine, such that if any portion of a region is in contact with metal residue 640 (which is in contact with ground via any of continuous lines 614, 624, or 634), the entirety of the region will bridged to ground and appears dark. If the line structures in each of the regions 612, 622, and 632 are end cap shorted, on the other hand, only the lines that are in contact with metal residue 640 (which is in contact with ground via any of continuous lines 614, 624, or 634), will bridged to ground and appear dark.

Similar to target 500 discussed above, based on the results of the measurements/inspection of target 600, the target 600 and/or regions within the target 600 may be assigned a clearing or process window score or merit function to represent the clearing fraction. For example, a merit function of the target 600 that is below a threshold, may indicate that all regions of the target 600 have been cleared and, accordingly, each area in nearby devices that corresponds to a region of the target 600 are likely cleared, and thus further material removal (CMP) may be stopped and inspection of nearby devices may be unnecessary. Alternatively, the merit function of the target 600 may be above a threshold indicating that one or more regions of the target 600 have not been adequately cleared and, accordingly, further material removal (CMP) is necessary and/or additional measurement/inspection of nearby devices for residue may be necessary. In some implementations, a merit function of specific regions of the target 600 may indicate that they have not been adequately cleared and, accordingly, the areas of nearby devices that correspond to these specific regions may require additional measurement/inspection. For example, as illustrated in FIG. 6B, measurement/inspection of regions 622a and 622b of structure 620 and regions 632c, 632d, and 632e of structure 630 may result in a merit function indicating that residue 640 is present in these regions, and accordingly, further material removal (CMP) is necessary and/or additional measurement/inspection for artifacts, such as residue, in areas of nearby devices that correspond to these regions may be necessary.

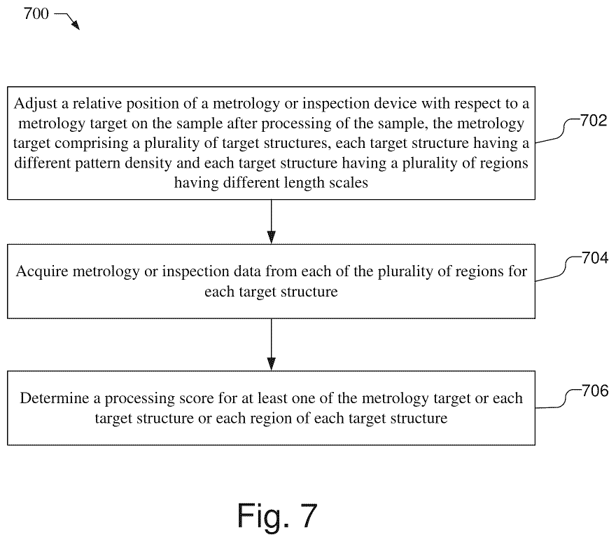

FIG. 7 is a flow chart 700 illustrating a method of measurement or inspection for processing of a sample using a metrology target as discussed herein.

As illustrated in block 702, the method includes adjusting a relative position of a metrology or inspection device, such as metrology tool 304 shown in FIGS. 3A and 3B or optical metrology device 400 shown in FIG. 4, with respect to a metrology target, such target 500 shown in FIGS. 5A and 5B or target 600 shown in FIG. 6A or 6B, on the sample after processing of the sample. The metrology target comprises a plurality of target structures, such as target structures 510, 520, and 530 shown in FIGS. 5A and 5B or target structures 610, 620, and 630 shown in FIG. 6A or 6B, each target structure having a different pattern density and each target structure having a plurality of regions having different length scales, such as regions 512, 522, and 532 shown in FIGS. 5A and 5B or regions 612, 622, 632 shown in FIG. 6A or 6B. For example, the plurality of target structures may comprise at least three test structures. The patterns in each test structure, for example, may be line structures (lines and spaces) with densities that range from at least 20% line/space density to 80% line/space density. The length scale for each region, for example, may be along an axis that is perpendicular to lines in each region.

In block 704, metrology or inspection data is acquired from each of the plurality of regions for each target structure, e.g., as discussed in reference to FIGS. 5B and 6B. For example, the location for the measurement or inspection for processing of the sample may be in a center of each region, e.g., as illustrated in FIG. 5B. In some implementations, the location for the measurement or inspection for processing of the sample may be the entirety of each region, e.g., as illustrated in FIG. 6B. The metrology or inspection device that acquires the metrology or inspection data, for example, may be a spectroscopic ellipsometer, a spectroscopic reflectometer, or an acoustic microscope. In some implementations, each target structure may further include separations between regions and a continuous line, e.g., lines 614, 624, and 634 shown in FIGS. 6A and 6B, that is coupled to ground and extends adjacent to each region within the separations between regions, and the metrology or inspection device may be a voltage contrast metrology device, such as a VC SEM.

In block 706, a processing score for at least one of the metrology target or each target structure or each region of each target structure is determined, e.g., as discussed in reference to FIGS. 5B and 6B. The processing score may be, e.g., process window score or merit function, which may represent the performance of the process. For example, the processing score may be determined by performing a differential or comparative analysis with respect to a reference region for each region in each target structure. The reference region, for example, may be a region with no pattern, such as regions 504 or 506 in FIGS. 5A and 5B or regions 604 or 606 in FIGS. 6A and 6B. In some implementations, the processing score comprises may be determined by comparing the metrology or inspection data acquired for each region in each target structure to an expected model or simulation result.

In some implementations, the processing score for the metrology target, each target structure, each region of each target structure, or any combination thereof may be reported. For example, the processing score(s) may be reported to a user or may be reported to another system, such as external process tools, in a feed forward or feedback process in order to adjust a process parameter associated with a fabrication process step of the samples based on the measurement results, e.g., as illustrated in FIGS. 3A and 3B.

In some implementations, the processing of the sample may be chemical-mechanical planarization (CMP) process, and the regions in the target structures may represent the processing performance in different areas in a device on the sample. For example, the target may serve as a proxy device that is representative of the behavior of a production die with respect to processing performance.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A metrology target for measurement or inspection for processing of a sample, comprising:
a plurality of target structures, each target structure having a different pattern density and each target structure having a plurality of regions having different length scales, wherein each region in each target structure comprises a location for the measurement or inspection for processing of the sample.

2. The metrology target of claim 1, wherein the metrology target is configured for measurement or inspection of a chemical-mechanical planarization (CMP) process, and the regions in the target structures represent a processing performance in different areas in a device on the sample.

3. The metrology target of claim 1, wherein the plurality of target structures are on a mask used to transfer patterns onto the sample.

4. The metrology target of claim 1, wherein the plurality of target structures are on the sample.

5. The metrology target of claim 1, wherein the plurality of target structures comprise at least three test structures, wherein patterns in the at least three test structures comprise patterns with densities that range from at least 20% density to 80% density.

6. The metrology target of claim 1, wherein a length scale for each region is along an axis that is perpendicular to lines in each region.

7. The metrology target of claim 1, wherein the location for the measurement or inspection for processing of the sample is in a center of each region.

8. The metrology target of claim 1, further comprising at least one region with no pattern.

9. The metrology target of claim 1, wherein the metrology target is configured for measurement or inspection by an optical metrology tool comprising at least one of a spectroscopic ellipsometer, spectroscopic reflectometer, and acoustic microscope.

10. The metrology target of claim 1, wherein each target structure further comprises separations between regions and a continuous line that is coupled to ground and extends adjacent to each region within the separations between regions, and the metrology target is configured for voltage contrast measurement.

11. A method of measurement or inspection for processing of a sample, comprising:
adjusting a relative position of a metrology or inspection device with respect to a metrology target on the sample after processing of the sample, the metrology target comprising a plurality of target structures, each target structure having a different pattern density and each target structure having a plurality of regions having different length scales;
acquiring metrology or inspection data from each of the plurality of regions for each target structure; and
determining a processing score for at least one of the metrology target or each target structure or each region of each target structure.

12. The method of claim 11, wherein the processing of the sample comprises a chemical-mechanical planarization (CMP) process, and the regions in the target structures represent a processing performance in different areas in a device on the sample.

13. The method of claim 11, wherein the plurality of target structures comprise at least three test structures, wherein patterns in the at least three test structures comprise patterns with densities that range from at least 20% density to 80% density.

14. The method of claim 11, wherein a length scale for each region is along an axis that is perpendicular to lines in each region.

15. The method of claim 11, wherein a location for the acquiring the metrology or inspection data is in a center of each region.

16. The method of claim 11, wherein the metrology or inspection device comprises at least one of a spectroscopic ellipsometer, spectroscopic reflectometer, and acoustic microscope.

17. The method of claim 11, wherein each target structure further comprises separations between regions and a continuous line that is coupled to ground and extends adjacent to each region within the separations between regions, and the metrology or inspection device comprises a voltage contrast metrology device.

18. The method of claim 11, wherein determining the processing score comprises performing a differential or comparative analysis with respect to a reference region for each region in each target structure.

19. The method of claim 18, wherein the reference region comprises a region with no pattern.

20. The method of claim 11, wherein determining the processing score comprises comparing the metrology or inspection data acquired for each region in each target structure to an expected model or simulation result.

21. A metrology target for measurement or inspection for processing of a sample, comprising:
at least three target structures, each target structure having a plurality of regions comprising lines and spaces, wherein each region in a target structure has different lengths along an axis that is perpendicular to the lines, and wherein each of the target structures has a different line/space density, wherein the regions in the target structures represent device characteristics that correspond to areas on nearby devices.
